(19) United States
(12) Patent Application Publication
(10) Pub. No.: US 2019/0113544 A1
(43) Pub. Date: Apr. 18, 2019

(54) MAGNETIC SENSOR AND CURRENT SENSOR INCLUDING THE SAME

(71) Applicant: TDK CORPORATION, TOKYO (JP)

(72) Inventors: Takashi Osada, Tokyo (JP); Takahiro Hamamura, Tokyo (JP); Tamon Kasajima, Tokyo (JP)

(73) Assignee: TDK CORPORATION, TOKYO (JP)

(21) Appl. No.: 16/153,432

(22) Filed: Oct. 5, 2018

(30) Foreign Application Priority Data
Oct. 12, 2017 (JP) 2017-198702

(51) Int. Cl. G01R 15/18; G01R 33/04; G01R 33/00; G01R 19/00

(52) U.S. Cl. CPC G01R 15/185; G01R 19/0092; G01R 33/0017; G01R 33/04

(57) ABSTRACT

Disclosed herein is a magnetic sensor that includes a saturable magnetic member that receives magnetic flux flowing in a first axis direction, and a detection coil wound around the saturable magnetic member and having a coil axis aligned with a predetermine direction different from the first axis direction.

### BACKGROUND OF THE INVENTION

### Field of the Invention

The present invention relates to a magnetic sensor and a current sensor having the same and, more particularly, to a magnetic sensor suitably used for a current sensor capable of measuring a large current and such a current sensor having the same.

### Description of Related Art

As a current sensor using a magnetic sensor, current sensors described in JP 11-258725 A and JP 2010-276422 A are known. The current sensors described in JP 11-258725 A and JP 2010-276422 A include a bus bar through which current to be measured flows and a magnetic sensor that receives magnetic flux generated by the current flowing through the bus bar. The magnetic sensor includes a saturable magnetic member and a coil wound around the saturable magnetic member.

In the current sensors described in JP 11-258725 A and JP 2010-276422 A, the direction of the magnetic flux generated by the current flowing through the bus bar and the coil axis direction are aligned with each other, so that the magnetic flux generated by the current flowing through the bus bar can be detected with high sensitivity.

However, when the direction of the magnetic flux generated by the current flowing through the bus bar and the coil axis direction are aligned with each other as in JP 11-258725 A and JP 2010-276422 A, the saturable magnetic member is easily magnetically saturated while high detection sensitivity can be obtained. Thus, it is difficult for the current sensors of JP 11-258725 A and JP 2010-276422 A to measure a large current.

### SUMMARY

It is therefore an object of the present invention to provide a current sensor capable of measuring a large current and a magnetic sensor used for the current sensor.

A magnetic sensor according to the present invention is a magnetic sensor for detecting magnetic flux flowing in a first axis direction and includes a saturable magnetic member that receives magnetic flux and a detection coil wound around the saturable magnetic member and having a coil axis aligned with a predetermine direction different from the first axis direction.

According to the present invention, the coil axis of the detection coil is aligned with a direction different from the direction of the magnetic flux, reducing magnetic influence of the magnetic flux on the coil axis direction of the saturable magnetic member. This makes the saturable magnetic member less likely to be magnetically saturated in the coil axis direction, allowing a strong magnetic field to be measured.

In the present invention, the predetermined direction may be substantially aligned with a second axis direction orthogonal to the first axis direction. This significantly reduces magnetic influence of the magnetic flux on the coil axis direction of the saturable magnetic member, further suppressing occurrence of magnetic saturation in the saturable magnetic member.

In the present invention, the saturable magnetic member may have a flat plate shape whose longitudinal direction is aligned with the predetermined direction, whose short length direction is aligned with a direction orthogonal to the longitudinal direction, and whose thickness direction is aligned with a direction orthogonal to the longitudinal and short length directions. Further, the size of the saturable magnetic member in the short length direction may be smaller than the size thereof in the longitudinal direction, and the size of the saturable magnetic member in the thickness direction may be smaller than the size thereof in the short length direction. With this configuration, the plate-shaped saturable magnetic member becomes less likely to be magnetically saturated.

In the present invention, the angle formed by the short length direction and the first axis direction may be larger than the angle formed by the short length direction and a third axis direction orthogonal to the first axis direction and second axis direction. This further suppresses the occurrence of magnetic saturation in the saturable magnetic member.

In the present invention, the thickness direction may be substantially aligned with the first axis direction, and the short length direction may be substantially aligned with the third axis direction. This configuration is a configuration in which the saturable magnetic member is least likely to be magnetically saturated, allowing a stronger magnetic field to be measured.

In the present invention, the saturable magnetic member may have a laminated structure in the thickness direction. This increases the sectional area of the saturable magnetic member, further suppressing the occurrence of magnetic saturation in the saturable magnetic member.

The magnetic sensor according to the present invention may further include a bobbin for fixing the angle formed by the longitudinal direction of the saturable magnetic member and the predetermined direction. This allows the angle between the saturable magnetic member and the detection coil to be fixed at a predetermined angle.

In the present invention, the saturable magnetic member may include a first section in which the angle formed by the longitudinal direction and the first axis direction is a first angle and a second section in which the angle formed by the longitudinal direction and the first axis direction is a second angle different from the first angle. This allows easiness of magnetic saturation of the saturable magnetic member to be finely adjusted.

The magnetic sensor according to the present invention may further include a compensation coil for canceling magnetic flux. This allows a so-called closed loop magnetic sensor to be obtained.

A current sensor according to the present invention includes the above-described magnetic sensor and a bus bar that generates magnetic flux by current to be measured. According to the present invention, the use of the magnetic sensor less likely to be magnetically saturated allows a large current to be measured.

The current sensor according to the present invention may further include a magnetic shield that covers the magnetic sensor and bus bar. This allows an environmental magnetic field as noise to be shielded.

As described above, according to the present invention, there can be provided a current sensor capable of measuring a large current and a magnetic sensor used for the current sensor.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a simplified outer appearance view for explaining the configuration of the main part of a current sensor according to a preferred embodiment of the present invention;

FIG. 2A is a simplified plan view of the main part of the current sensor shown in FIG. 1 as viewed in the z-direction;

FIG. 2B is a simplified side view of the main part of the current sensor shown in FIG. 1 as viewed in the y-direction;

FIG. 3 is a simplified outer appearance view for explaining the configuration of the magnetic sensor;

FIG. 4 is a schematic perspective view of a saturable magnetic member having a multilayered structure;

FIG. 5 is a block diagram illustrating the circuit configuration of the current sensor;

FIG. 6 is a circuit diagram of the self-oscillation circuit;

FIG. 7 is a waveform diagram of an oscillation signal;

FIGS. 8A and 8B are graphs for explaining magnetic characteristics of the saturable magnetic member in a case where an external magnetic field Hₑₓₜ is zero, where FIG. 8A illustrates the entire major loop, and FIG. 8B illustrates an actual transition region;

FIGS. 9A and 9B are graphs for explaining magnetic characteristics of the saturable magnetic member in a case where the external magnetic field Hₑₓₜ exists, where FIG. 9A illustrates the entire major loop, and FIG. 9B illustrates an actual transition region;

FIG. 10 is a waveform diagram illustrating a change in the voltage applied to the resistance;

FIG. 11 is a waveform diagram illustrating a change in the oscillation signal and a change in the inverse oscillation signal;

FIG. 12 is a view for schematically explaining the flow of the magnetic flux passing through the saturable magnetic member and illustrates a case where the installation direction of the saturable magnetic member is set as illustrated in FIG. 3;

FIG. 13 is a simplified outer appearance view for explaining another example of the posture of the saturable magnetic member;

FIG. 14 is a view for schematically explaining the flow of the magnetic flux passing through the saturable magnetic member and illustrates a case where the installation direction of the saturable magnetic member is set as illustrated in FIG. 13;

FIG. 15 is a schematic diagram for explaining an appearance with rotating the saturable magnetic member about the x-axis;

FIG. 16 is a schematic diagram for explaining an appearance with rotating the saturable magnetic member about the y-axis;

FIG. 17 is a simplified cross-sectional view illustrating an example in which the saturable magnetic member is housed in a bobbin; and

FIGS. 18A and 18B are cross-sectional views schematically illustrating modifications of the saturable magnetic member.

### DETAILED DESCRIPTION OF THE EMBODIMENTS

Preferred embodiments of the present invention will be explained below in detail with reference to the accompanying drawings.

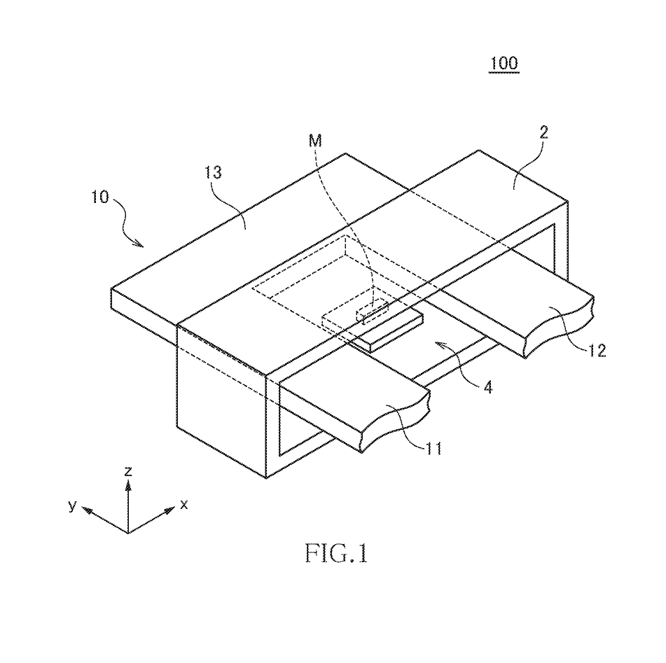

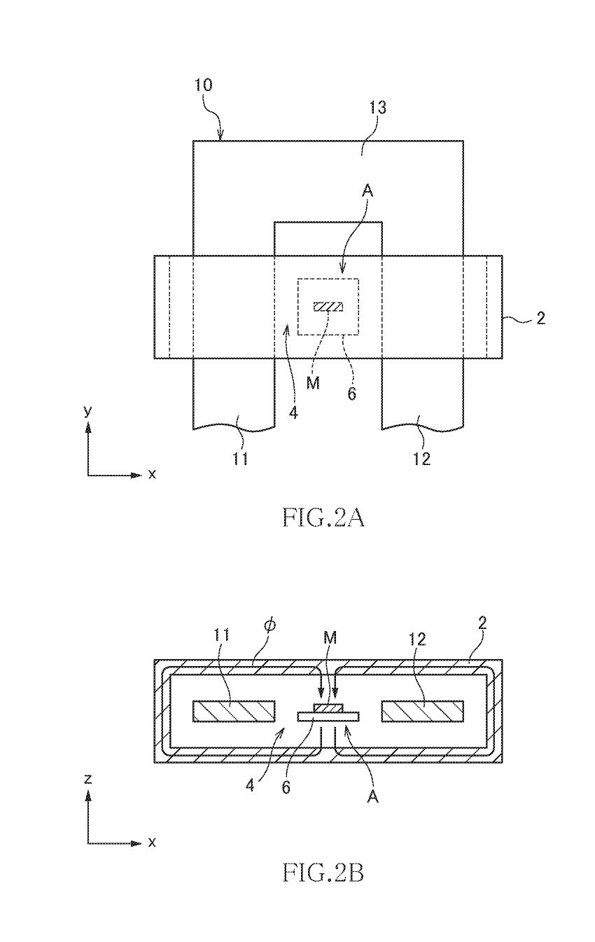

FIG. 1 is a simplified outer appearance view for explaining the configuration of the main part of a current sensor 100 according to a preferred embodiment of the present invention. FIG. 2A is a simplified plan view of the main part of the current sensor 100 as viewed in the z-direction, and FIG. 2B is a simplified side view of the main part of the current sensor 100 as viewed in the y-direction.

As illustrated in FIG. 1, FIG. 2A, and FIG. 2B, the current sensor 100 according to the present embodiment includes a bus bar 10, a magnetic sensor M that receives magnetic flux generated by current flowing through the bus bar 10, and a magnetic shield 2 that covers the magnetic sensor M and bus bar 10. The magnetic shield 2 is an annular-shaped magnetic member having a space part 4 extending in the y-direction, and a part of the bus bar 10 and the entire magnetic sensor M are disposed in the space part 4. As the material for the magnetic shield 2, a high permeability material such as ferrite, a grain-oriented silicon steel plate, or permalloy can be used. The magnetic shield 2 can shield an environmental magnetic field as noise and functions as a magnetic path for the magnetic flux generated by the current flowing through the bus bar 10.

The bus bar 10 is a member through which current to be measured flows and includes current paths 11 and 12 extending in the y-direction and a current path 13 extending in the x-direction. End portions of the respective current paths 11 and 12 are connected to each other through the current path 13. As a result, in the bus bar 10, current flows from the current path 11, through the current path 13, to the current path 12, or flows from the current path 12, through the current path 13, to the current path 11, so that as illustrated in FIG. 2B, z-direction magnetic flux ϕ is generated in a region A surrounded by the current paths 11 to 13.

A substrate 6 having the magnetic sensor M thereon is disposed in the region A surrounded by the current paths 11 to 13. As a result, the magnetic flux ϕ flowing in the z-direction is given to the magnetic sensor M. The strength and direction of the magnetic flux ϕ are determined by the amount and direction of the current flowing through the bus bar 10.

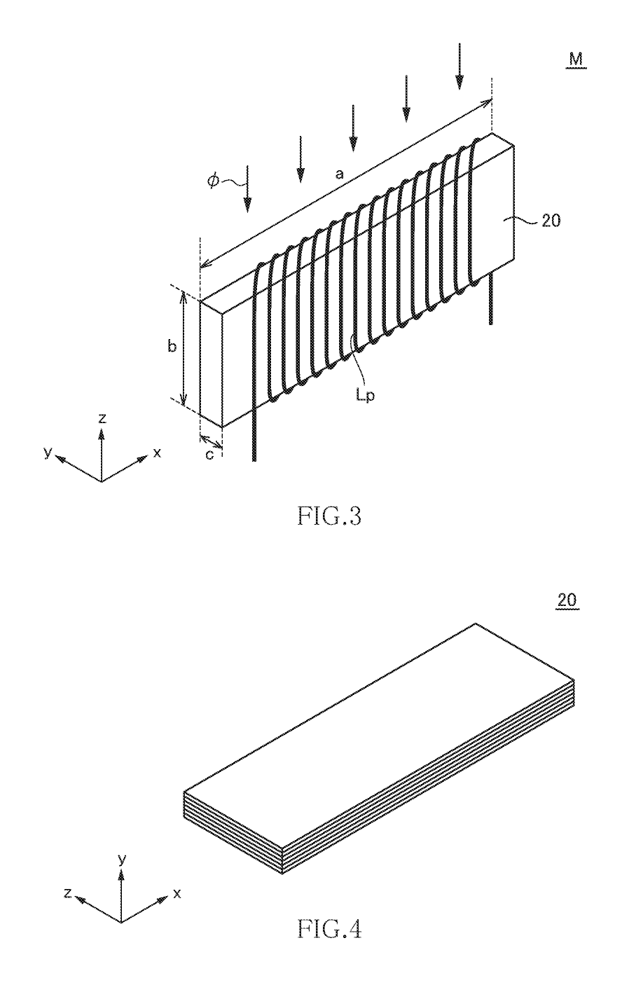

FIG. 3 is a simplified outer appearance view for explaining the configuration of the magnetic sensor M.

As illustrated in FIG. 3, the magnetic sensor M includes a saturable magnetic member 20 and a detection coil Lp wound around the saturable magnetic member 20. The saturable magnetic member 20 has a flat plate shape. Assuming that the size of the saturable magnetic member 20 in the longitudinal direction thereof is a, that in the short length direction is b, and that in the thickness direction is c, a>b>c is satisfied. In the example of FIG. 3, the detection coil Lp is wound such that the longitudinal direction of the saturable magnetic member 20 is aligned with the coil axis direction. The detection coil Lp may be wound directly on the saturable magnetic member 20 or wound around a bobbin housing the saturable magnetic member 20.

The longitudinal direction of the saturable magnetic member 20, i.e., the coil axis direction of the detection coil Lp differs from the z-direction. That is, the coil axis direction of the detection coil Lp differs from the direction of the magnetic flux ϕ to be detected. In the example of FIG. 3, the longitudinal direction of the saturable magnetic member 20 (coil axis direction of the detection coil Lp) is aligned with the x-direction, the short length direction thereof is aligned with the z-direction, and the thickness direction thereof is aligned with the y-direction. Therefore, in the present example, the angle formed by the direction of the magnetic flux ϕ (z-direction) and the longitudinal direction of the saturable magnetic member 20 (x-direction) is 90°.

Although there is no particular limitation on the material for the saturable magnetic member 20, amorphous magnetic metal is preferably used. The amorphous magnetic metal may have a single layer structure or may have a structure obtained by laminating a plurality of amorphous magnetic metal films in the thickness direction as illustrated in FIG. 4. The saturable magnetic member 20 having the laminated structure has an increased sectional area, making the saturable magnetic member 20 less likely to be magnetically saturated.

The relationship between the mounting direction of the saturable magnetic member 20 and the magnetic flux ϕ will be described later.

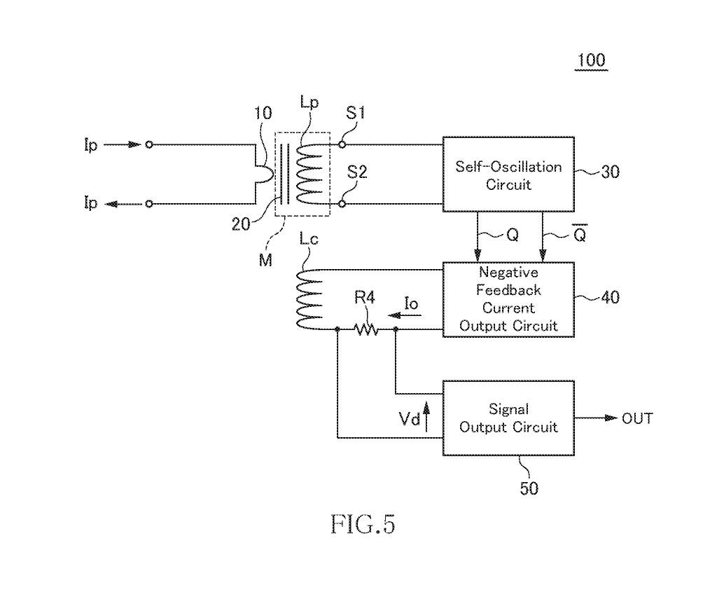

FIG. 5 is a block diagram illustrating the circuit configuration of the current sensor 100.

As illustrated in FIG. 5, the current sensor 100 according to the present embodiment includes a self-oscillation circuit 30 connected to the magnetic sensor M, a negative feedback current output circuit 40 that receives an oscillation signal Q and an inverse oscillation signal /Q which are generated by the self-oscillation circuit 30, a compensation coil Lc through which a negative feedback current Io generated by the negative feedback current output circuit 40 flows, and a signal output circuit 50 that generates an sensor output OUT based on the negative feedback current Io.

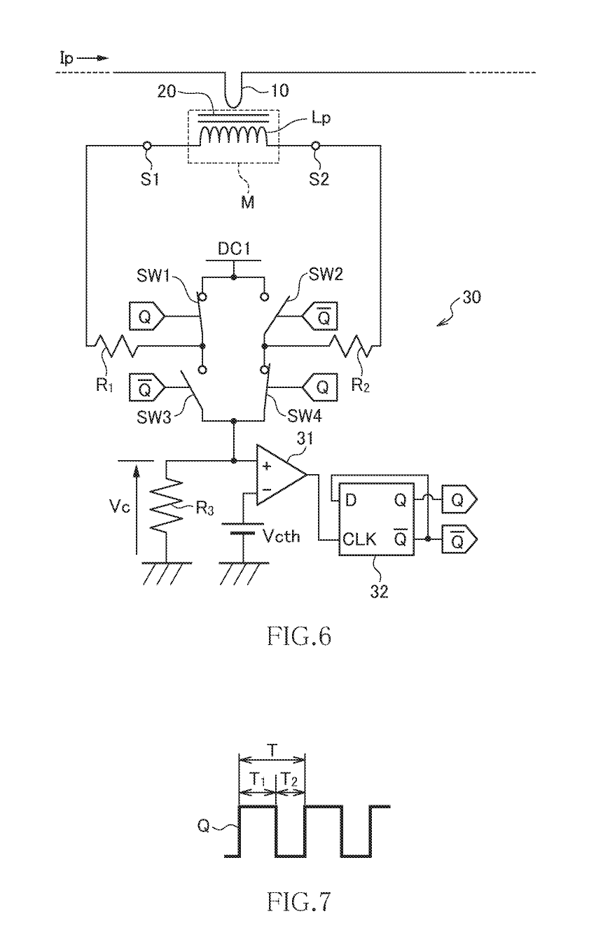

FIG. 6 is a circuit diagram of the self-oscillation circuit 30.

As illustrated in FIG. 6, the self-oscillation circuit 30 is an H-bridge type self-oscillation circuit and includes switches SW1 to SW4, resistances R1 to R3, a comparator 31, and a flip-flop circuit 32. The switches SW1 and SW3 are connected in series to each other, and the connection point therebetween is connected to one end S1 of the detection coil Lp through the resistance R1. Similarly, the switches SW2 and SW4 are connected in series to each other, and the connection point therebetween is connected to the other end S2 of the detection coil Lp through the resistance R2. The switches SW1 and SW2 are connected in common to a DC power supply DC1, and the switches SW3 and SW4 are grounded through the resistance R3.

The non-inversion input terminal (+) of the comparator 31 is connected to the resistance R3, and the inversion input terminal (−) thereof is applied with a reference voltage Vcth. Thus, when a voltage Vc applied to the resistance R3 exceeds the reference voltage Vcth, the output signal of the comparator 31 is changed to high level.

The output signal of the comparator 31 is input to the clock node of the flip-flop circuit 32. The oscillation signal Q output from the flip-flop circuit 32 controls the switches SW1 and SW4, and inverse oscillation signal /Q output therefrom controls the switches SW2 and SW3. The inverse oscillation signal /Q is fed back to the data node of the flip-flop circuit 32. Thus, the logic levels of the respective oscillation signal Q and inverse oscillation signal /Q output from the flip-flop circuit 32 are inverted every time the output signal of the comparator 31 is changed from low level to high level.

When the self-oscillation circuit 30 illustrated in FIG. 6 is powered ON, a first state and a second state alternately appear. In the first state, the switches SW1 and SW4 are turned ON, while the switches SW2 and SW3 are turned OFF. In the second state, the switches SW2 and SW3 are turned ON, while the switches SW1 and SW4 are turned OFF. In the first state, current flows from a power supply line applied with the power supply voltage DC1 and passes through the switch SW1, resistance R1, detection coil Lp, resistance R2, switch SW4, and resistance R3. As a result, the voltage Vc applied to the resistance R3 is gradually increased and, when the voltage Vc exceeds the reference voltage Vcth, the output signal of the comparator 31 is changed from low level to high level.

When the output signal of the comparator 31 is changed to high level, the logic levels of the respective oscillation signal Q and inverse oscillation signal /Q output from the flip-flop circuit 32 are inverted to make the state of the self-oscillation circuit 30 transit to the second state. In the second state, the switches SW2 and SW3 are turned ON, while the switches SW1 and SW4 are turned OFF, making current flow from the power supply line applied with the power supply voltage DC1 and pass through the switch SW2, resistance R2, detection coil Lp, resistance R1, switch SW3, and resistance R3. As a result, the voltage Vc applied to the resistance R3 is gradually increased and, when the voltage Vc exceeds the reference voltage Vcth, the output signal of the comparator 31 is changed from low level to high level.

The repetition of the above operation makes the self-oscillation circuit 30 alternately transit to the first and second states. As a result, the polarity of the voltage applied to the both ends of the detection coil Lp is periodically inverted, so that the oscillation signal Q has a waveform in which high level and low level are alternately repeated, as illustrated in FIG. 7. The symbol T of FIG. 7 indicates the oscillation period of the self-oscillation circuit 30, the symbol T₁ indicates the duration of the first state, and the symbol T₂ indicates the duration of the second state. The oscillation period T of the self-oscillation circuit 30 or duty of the oscillation signal Q is changed according to the permeability of the saturable magnetic member 20. Hereinafter, this point will be described.

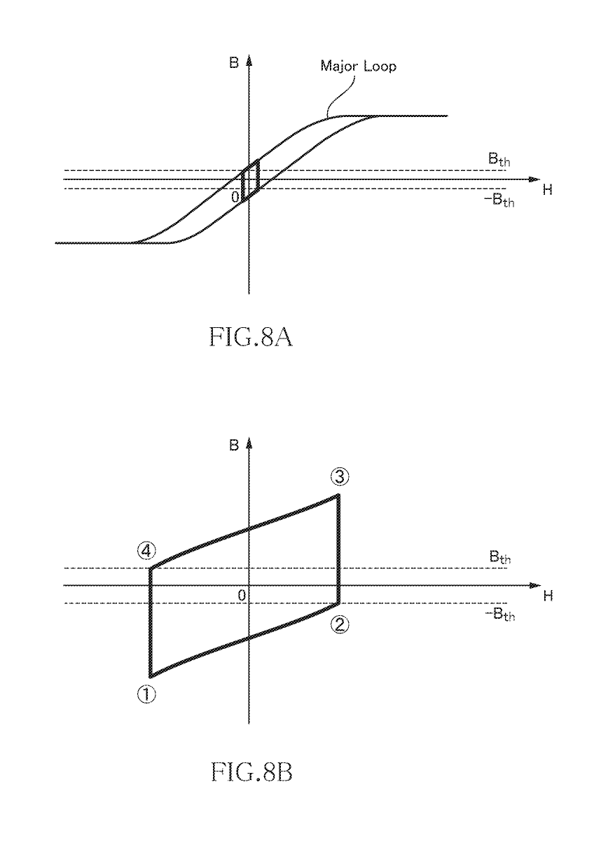

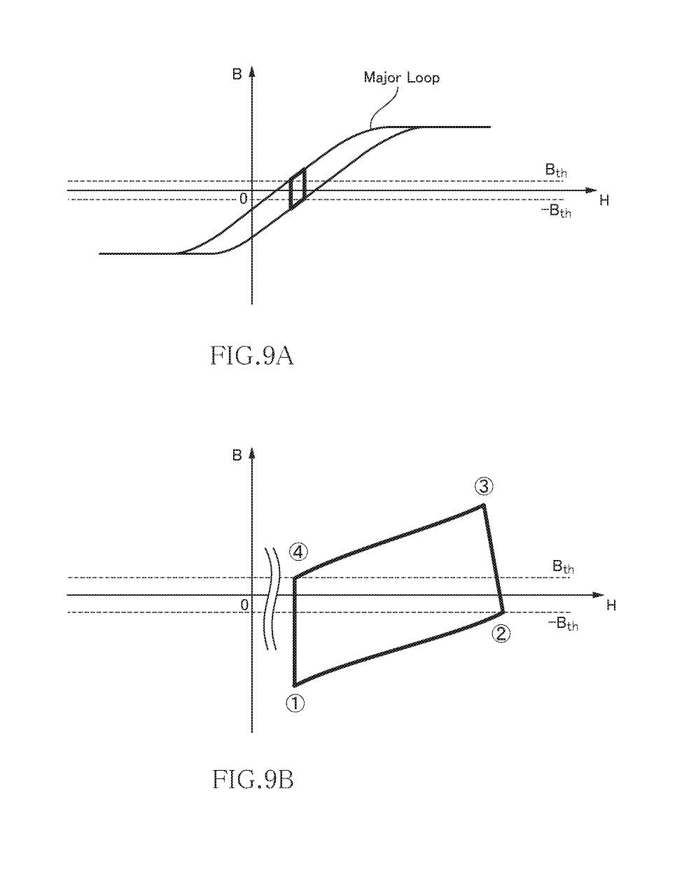

FIGS. 8A and 8B and FIGS. 9A and 9B are graphs for explaining magnetic characteristics of the saturable magnetic member 20. FIGS. 8A and 8B illustrate a case where an external magnetic field Hₑₓₜ is zero, and FIGS. 9A and 9B illustrate a case where the external magnetic field Hₑₓₜ exists. In all the above graphs, the horizontal axis indicates a magnetic field strength H, and the vertical axis indicates a magnetic flux density B. Further, FIGS. 8A and 9A illustrate the entire major loop, and FIGS. 8B and 9B illustrate an actual transition region.

As illustrated in FIGS. 8A and 8B, when the external magnetic field Hₑₓₜ is zero (when current Ip does not flow in the bus bar 10), a BH curve (point 1→point 2) appearing when a magnetic field given by the detection coil Lp is changed in one direction and a BH curve (point 3→point 4) appearing when a magnetic field given by the detection coil Lp is changed in the direction opposite to the one direction are symmetric to each other. The point 2 refers to a point at which the magnetic flux density B assumes a predetermined value −Bₜₕ when the magnetic field given by the detection coil Lp is changed in the one direction. Similarly, the point 4 refers to a point at which the magnetic flux density B assumes a predetermined value Bₜₕ when a magnetic field given by the detection coil Lp is changed in the direction opposite to the one direction.

The case where a magnetic field given by the detection coil Lp is changed in one direction refers to a state in which current flows from the terminal S1 to the terminal S2 which are illustrated in FIG. 6, i.e., the first state. On the other hand, the case where a magnetic field given by the detection coil Lp is changed in the opposite direction to the one direction refers to a state in which current flows from the terminal S2 to the terminal S1 which are illustrated in FIG. 6, i.e., the second state. When the external magnetic field Hₑₓₜ is zero (when current Ip does not flow in the bus bar 10), the BH curves are symmetric to each other, so that the duty of the oscillation signal Q is 50%.

On the other hand, when the external magnetic field Hₑₓₜ exists (when the current Ip flows in the bus bar 10), the BH curves are shifted by the amount corresponding to the strength of the external magnetic field Hₑₓt as illustrated in FIGS. 9A and 9B. As a result, the BH curve (point 1→point 2) appearing when a magnetic field given by the detection coil Lp is changed in one direction and the BH curve (point 3→point 4) appearing when a magnetic field given by the detection coil Lp is changed in the direction opposite to the one direction are asymmetric to each other. Thus, the duty of the oscillation signal Q deviates from 50%.

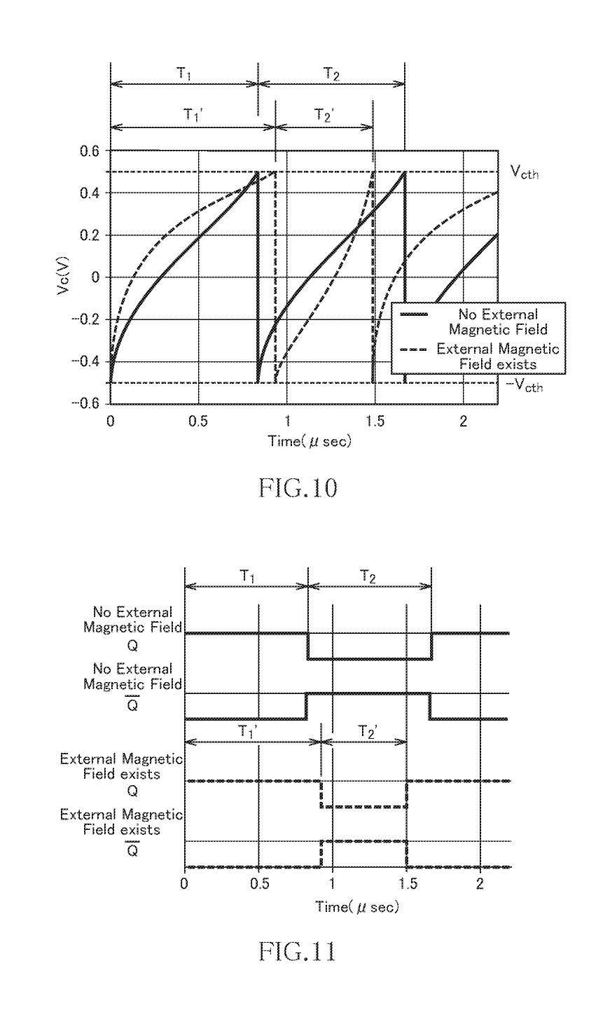

FIG. 10 is a waveform diagram illustrating a change in the voltage Vc applied to the resistance R3, and FIG. 11 is a waveform diagram illustrating a change in the oscillation signal Q and a change in the inverse oscillation signal/Q. In both FIGS. 10 and 11, the continuous line indicates the case where the external magnetic field Hₑₓₜ is zero (when current Ip does not flow in the bus bar 10), and the dashed line indicates the case where the external magnetic field Hₑₓₜ exists (when the current Ip flows in the bus bar 10).

As illustrated in FIG. 10, in both cases where the external magnetic field Hₑₓₜ is zero and where the external magnetic field Hₑₓₜ exists, the voltage Vc is inverted in polarity every time it reaches the reference voltage Vcth with the lapse of time and drops to −Vcth instantaneously. The level of the Vcth corresponds to the value Bₜₕ shown in FIGS. 8A and 8B and FIGS. 9A and 9B, and the level of the −Vcth corresponds to the value −Bₜₕ shown in FIGS. 8A and 8B and FIGS. 9A and 9B. When the external magnetic field Hₑₓₜ is zero, the BH curves are symmetric, so that the duty of the oscillation signal Q is 50% (T₁=T₂) as illustrated in FIG. 11. On the other hand, when the external magnetic field Hₑₓₜ exists, the BH curves are asymmetric, so that the duty of the oscillation signal Q exceeds 50% (T₁′>T₂′) as illustrated in FIG. 11, and the saturable magnetic member 20 is magnetically saturated to reduce the inductance of the detection coil Lp, whereby the oscillation period T of the oscillation signal Q is shortened. That is, the oscillation frequency of the self-oscillation circuit 30 becomes high.

The oscillation signal Q and inverse oscillation signal /Q generated by the self-oscillation circuit 30 is fed to the negative feedback current output circuit 40 as illustrated in FIG. 5. The negative feedback current output circuit 40 monitors the duties or frequencies of the respective oscillation signal Q and inverse oscillation signal /Q and generates the negative feedback current Io based on the monitored duties or frequencies. For example, the negative feedback current output circuit 40 controls the generation amount of the negative feedback current Io such that it increases as the duties of the respective oscillation signal Q and inverse oscillation signal /Q deviate from 50%. The generated negative feedback current Io is fed to the compensation coil Lc to cancel magnetic flux generated by the bus bar 10. By the above closed loop control, the magnetic flux generated by the bus bar 10 is always canceled to make the duty of the oscillation signal Q be 50%.

The negative feedback current Io is converted into the voltage Vd by the resistance R4 connected in series to the compensation coil Lc, and the level of the voltage Vd is detected by the signal output circuit 50. The signal output circuit 50 generates the sensor output OUT based on the voltage Vd and outputs it to an external device. The output OUT is a signal indicating the amount of the current Ip flowing through the bus bar 10.

The current sensor 100 according to the present embodiment measures the amount of the current flowing through the bus bar 10 according to such a principle.

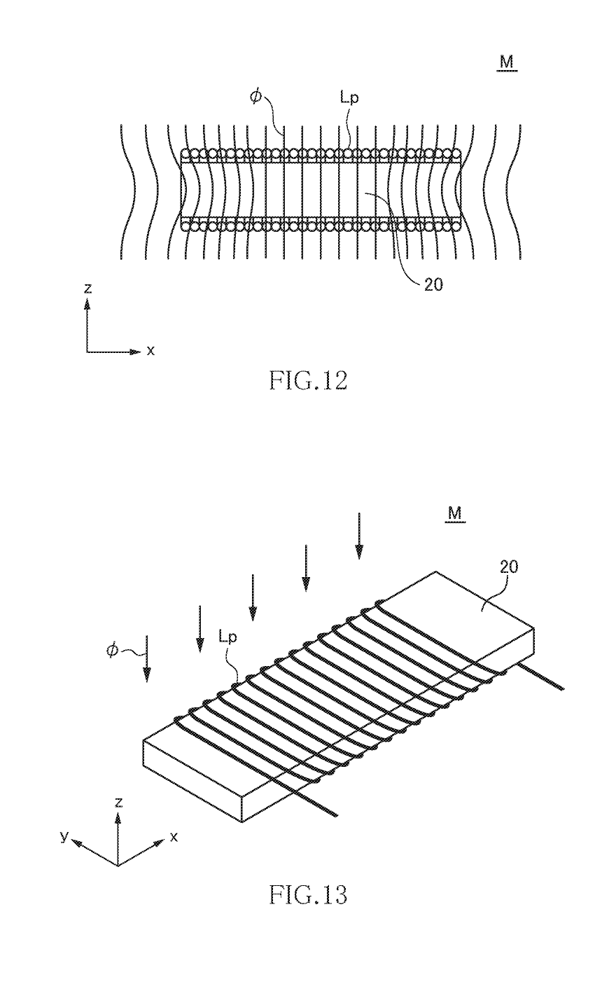

FIG. 12 is a view for schematically explaining the flow of the magnetic flux ϕ passing through the saturable magnetic member 20 and illustrates a case where the installation direction of the saturable magnetic member 20 is set as illustrated in FIG. 3.

As illustrated in FIG. 12, the magnetic flux ϕ flows in the z-direction and, accordingly, it flows inside the saturable magnetic member 20 in the z-direction in the vicinity of the center thereof in the x-direction. Thus, in this area, no x-direction component is included in the magnetic flux ϕ, and sensitivity with respect to the detection coil Lp is substantially zero. On the other hand, in the vicinity of the end portions of the saturable magnetic member 20 in the x-direction, the magnetic flux ϕ is attracted from the surrounding area, so that an x-direction component is generated in the magnetic flux ϕ flowing inside the saturable magnetic member 20. Thus, in this area, the inductance of the detection coil Lp is changed according to the density of the magnetic flux ϕ, so that sensitivity with respect to the detection coil Lp occurs. That is, the sensor output OUT is linearly changed according to the density of the magnetic flux ϕ.

Then, when the density of the magnetic flux ϕ becomes high, a magnetic saturation region is enlarged from the end portions of the saturable magnetic member 20 in the x-direction, and when the density of the magnetic flux ϕ exceeds a certain value, the saturable magnetic member 20 is completely magnetically saturated, preventing further measurement of the density of the magnetic flux ϕ. When the installation direction of the saturable magnetic member 20 is set as illustrated in FIG. 3, the direction of the magnetic flux ϕ (z-direction) and the coil axis direction of the detection coil Lp (x-direction) are orthogonal, making magnetic saturation less likely to occur than when the direction of the magnetic flux ϕ and the coil axis direction of the detection coil are aligned with each other as in conventional general current sensors. Thus, it is possible to measure even a large current flowing through the bus bar 10 without causing the saturable magnetic member 20 to be easily saturated.

FIG. 13 is a simplified outer appearance view for explaining another example of the posture of the saturable magnetic member 20.

In the example of FIG. 13, the longitudinal direction of the saturable magnetic member 20 (coil axis direction of the detection coil Lp) is aligned with the x-direction, the short length direction thereof is aligned with the y-direction, and the thickness direction thereof is aligned with the z-direction. Even in this installation state, the angle formed by the flowing direction of the magnetic flux ϕ (z-direction) and the longitudinal direction of the saturable magnetic member 20 (x-direction) is 90°, making the saturable magnetic member 20 less likely to be magnetically saturated in the x-direction as in the example of FIG. 3.

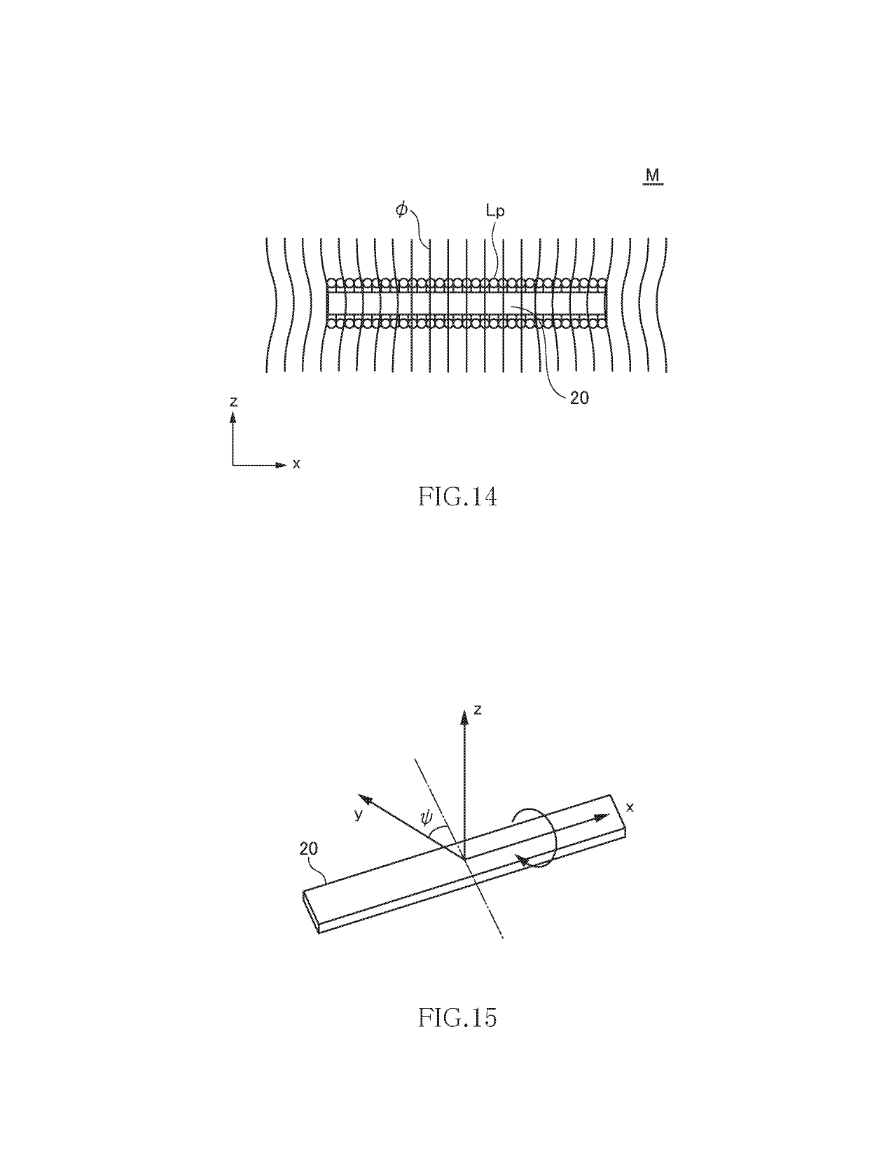

FIG. 14 is a view for schematically explaining the flow of the magnetic flux ϕ passing through the saturable magnetic member 20 and illustrates a case where the installation direction of the saturable magnetic member 20 is set as illustrated in FIG. 13.

As illustrated in FIG. 14, when the installation direction of the saturable magnetic member 20 is set as illustrated in FIG. 13, the amount of the magnetic flux ϕ attracted from the surrounding area to the saturable magnetic member 20 is reduced. That is, the x-direction component of the magnetic flux ϕ inside the saturable magnetic member 20 is reduced as compared to the example of FIG. 12. This is because the passing distance of the magnetic flux ϕ in the saturable magnetic member 20 becomes the shortest since the thickness direction of the saturable magnetic member 20 is aligned with the z-direction. Thus, the magnetic flux density at which the saturable magnetic member 20 is magnetically saturated becomes higher, allowing a larger current to be measured.

The installation states illustrated in FIGS. 3 and 13 are the same as each other in that the flowing direction of the magnetic flux ϕ (z-direction) and the longitudinal direction of the saturable magnetic member 20 (x-direction) are orthogonal and differ from each other on whether the short length direction of the saturable magnetic member 20 is aligned with the z-direction or y-direction. The short length direction of the saturable magnetic member 20 need not necessarily be completely aligned with the z-direction or y-direction, but it is possible to set an angle Ψ of the saturable magnetic member 20 in the short length direction to a desired angle by rotating the saturable magnetic member 20 about the x-axis as illustrated in FIG. 15. The angle Ψ is an angle formed by the short length direction of the saturable magnetic member 20 and the y-direction.

The smaller the angle Ψ is, the less likely the saturable magnetic member 20 is to be magnetically saturated in the x-direction. Therefore, in order to allow measurement of a larger current, the angle Ψ is preferably set smaller than 45°. In other words, the angle Ψ formed by the short length direction of the saturable magnetic member 20 and the y-direction is preferably smaller than the angle formed by the short length direction of the saturable magnetic member 20 and the z-direction.

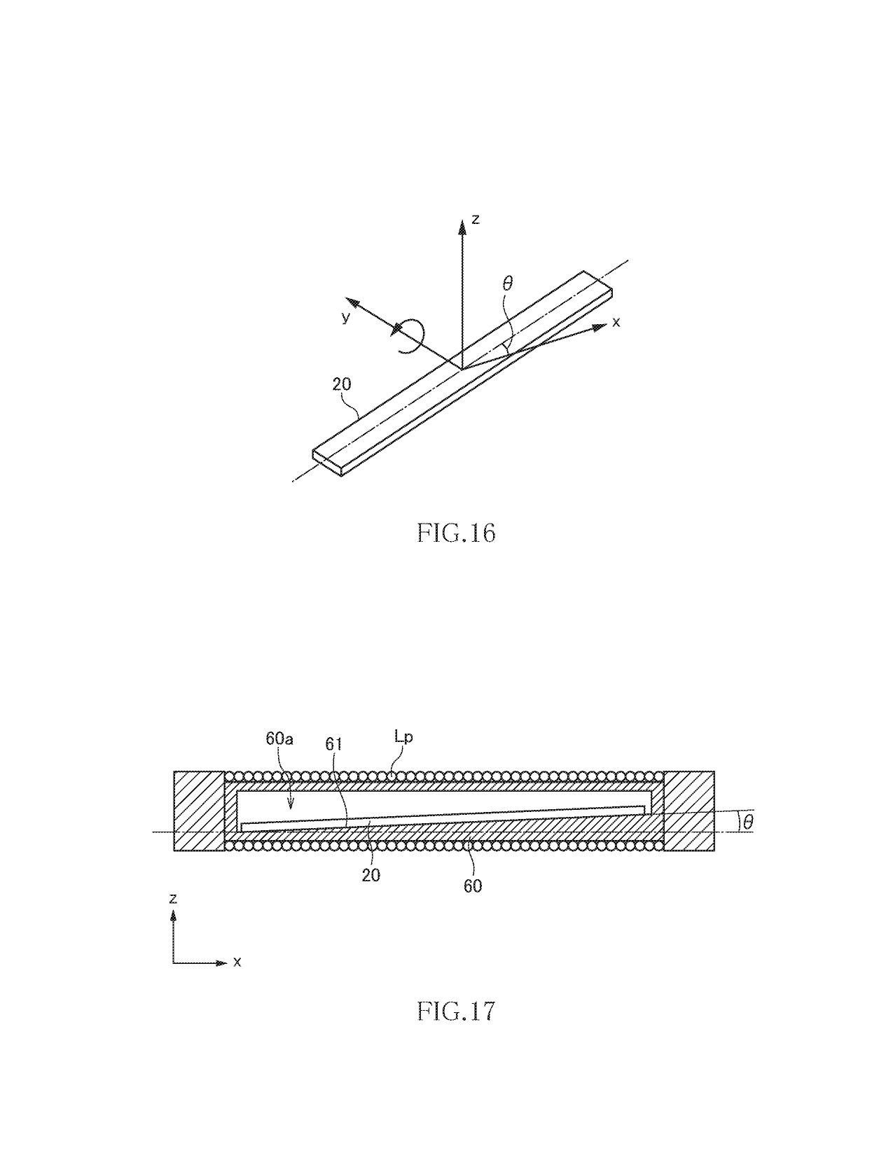

Further, in the present invention, the longitudinal direction of the saturable magnetic member 20 need not necessarily be completely aligned with the x-direction, and it is possible to set an angle θ of the saturable magnetic member 20 in the longitudinal direction to a desired angle other than 0° by rotating the saturable magnetic member 20 about the y-axis as illustrated in FIG. 16. The angle θ is an angle formed by the longitudinal direction of the saturable magnetic member 20 and the x-direction.

The closer the angle θ is to 0°, the less likely the saturable magnetic member 20 is to be magnetically saturated in the x-direction. The angle θ has significant influence on easiness of the magnetic saturation, so that it is preferable to set the angle θ equal to or smaller than 100 so as to suppress the magnetic saturation.

FIG. 17 is a simplified cross-sectional view illustrating an example in which the saturable magnetic member 20 is housed in a bobbin 60.

The bobbin 60 illustrated in FIG. 17 has a housing part 60a for housing the saturable magnetic member 20, and a predetermined inner wall 61 constituting the housing part 60a is inclined by the angle θ with respect to the x-direction. Thus, it is only necessary to position the saturable magnetic member 20 on the inner wall 61 to allow the angle formed by the longitudinal direction of the saturable magnetic member 20 and the x-direction to be reliably fixed to 0°. As described above, the angle θ is preferably equal to or smaller than 10°. The detection coil Lp is wound around the outer periphery of the bobbin 60. Also in the example of FIG. 17, the coil axis of the of the detection coil Lp is aligned with the x-direction. As described above, in the present invention, the longitudinal direction of the saturable magnetic member 20 and the coil axis direction of the detection coil Lp need not be completely aligned with each other.

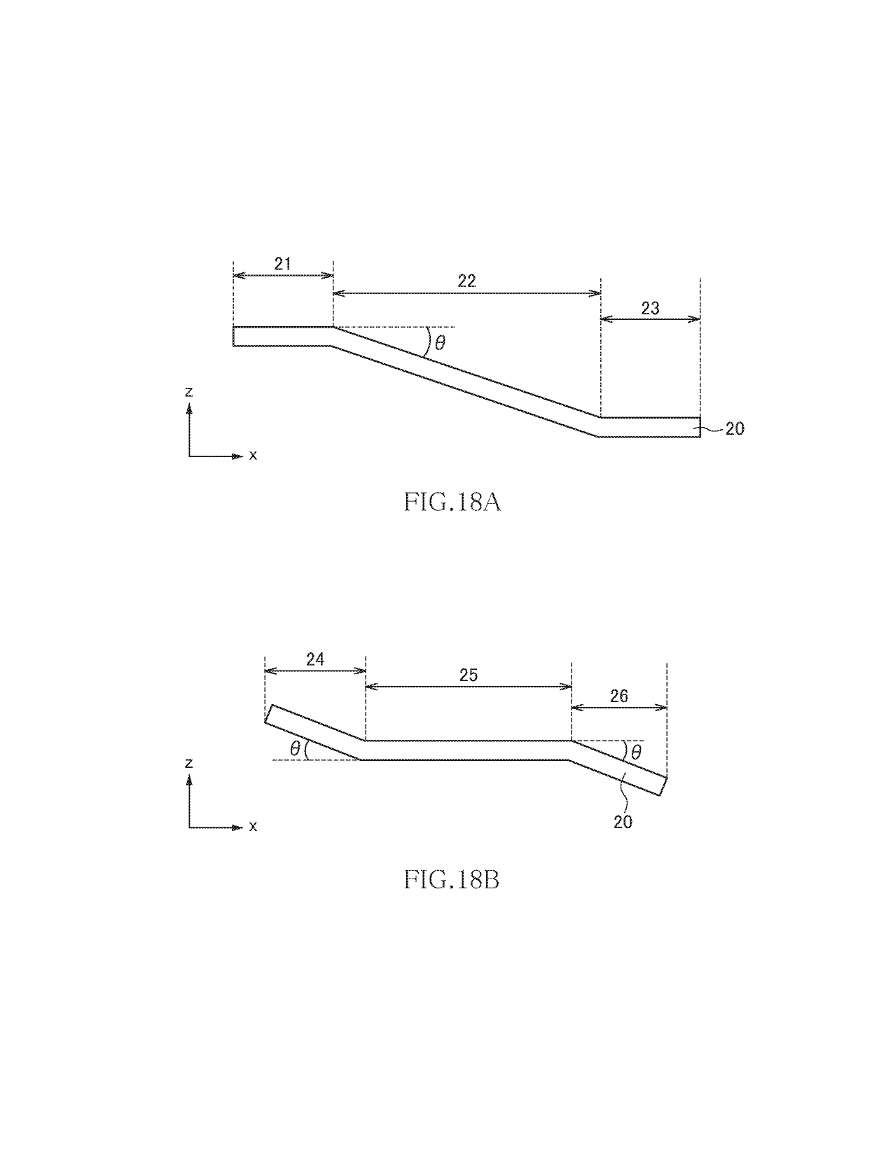

FIGS. 18A and 18B are cross-sectional views schematically illustrating modifications of the saturable magnetic member 20, respectively.

In the example illustrated in FIG. 18A, the saturable magnetic member 20 is divided into three sections 21 to 23. In the sections 21 and 23, the angle θ with respect to the x-direction is substantially 0°, and in the section 22 positioned between the sections 21 and 23, the angle θ with respect to the x-direction is larger than 0° and equal to or smaller than 10°. In the example illustrated in FIG. 18B, the saturable magnetic member 20 is divided into three sections 24 to 26. In the section 25, the angle θ with respect to the x-direction is substantially 0°, and in the sections 24 and 26 positioned on both sides of the section 25 in the longitudinal direction of the saturable magnetic member 20, the angle θ with respect to the x-direction is larger than 0° and equal to or smaller than 10°.

As described above, the saturable magnetic member 20 is divided into a plurality of sections in the longitudinal direction, and the angle θ is set to a predetermined value for each section. With this configuration, easiness of magnetic saturation of the saturable magnetic member 20 can be adjusted more finely than in a case where the entire saturable magnetic member 20 is inclined.

It is apparent that the present invention is not limited to the above embodiments, but may be modified and changed without departing from the scope and spirit of the invention.

What is claimed is:

1. A magnetic sensor comprising:
a saturable magnetic member that receives magnetic flux flowing in a first axis direction; and
a detection coil wound around the saturable magnetic member and having a coil axis aligned with a predetermine direction different from the first axis direction.

2. The magnetic sensor as claimed in claim 1, wherein the predetermined direction is substantially aligned with a second axis direction orthogonal to the first axis direction.

3. The magnetic sensor as claimed in claim 2,
wherein the saturable magnetic member has a flat plate shape whose longitudinal direction is aligned with the predetermined direction, whose short length direction is aligned with a direction orthogonal to the longitudinal direction, and whose thickness direction is aligned with a direction orthogonal to the longitudinal and short length directions, and
wherein a size of the saturable magnetic member in the short length direction is smaller than a size thereof in the longitudinal direction, and a size of the saturable magnetic member in the thickness direction is smaller than the size thereof in the short length direction.

4. The magnetic sensor as claimed in claim 3, wherein an angle formed by the short length direction and the first axis direction is larger than an angle formed by the short length direction and a third axis direction orthogonal to the first axis direction and second axis direction.

5. The magnetic sensor as claimed in claim 4, wherein the thickness direction is substantially aligned with the first axis direction, and the short length direction is substantially aligned with the third axis direction.

6. The magnetic sensor as claimed in claim 3, wherein the saturable magnetic member has a laminated structure in the thickness direction.

7. The magnetic sensor as claimed in claim 1, further comprising a bobbin for fixing an angle formed by a longitudinal direction of the saturable magnetic member and the predetermined direction.

8. The magnetic sensor as claimed in claim 1, wherein the saturable magnetic member includes a first section in which an angle formed by a longitudinal direction and the first axis direction is a first angle and a second section in which an angle formed by the longitudinal direction and the first axis direction is a second angle different from the first angle.

9. The magnetic sensor as claimed in claim 1, further comprising a compensation coil for canceling the magnetic flux.

10. A current sensor comprising:
a bus bar that generates magnetic flux flowing in a first axis direction by current to be measured; and
a magnetic sensor for detecting the magnetic flux, the magnetic sensor comprising:
a saturable magnetic member that receives the magnetic flux; and
a detection coil wound around the saturable magnetic member and having a coil axis aligned with a predetermine direction different from the first axis direction.

11. The current sensor as claimed in claim 10, further comprising a magnetic shield that covers the magnetic sensor and bus bar.

12. An apparatus comprising:
a bus bar including first and second current paths extending in a first direction and arranged in a second direction orthogonal to the first direction, current to be measured flowing through the first and second current paths in an opposite direction to each other;
a magnetic member disposed between the first and second current paths in the second direction; and
a coil wound around the magnetic member and having a coil axis aligned with a predetermine direction different from a third direction orthogonal to the first and second directions.

13. The apparatus as claimed in claim 12, wherein the coil axis is substantially perpendicular to the third direction.

14. The apparatus as claimed in claim 12, wherein the magnetic member has a longitudinal direction that is substantially perpendicular to the third direction.

15. The apparatus as claimed in claim 12,
wherein the magnetic member has a longitudinal direction, and
wherein the longitudinal direction and the coil axis form a predetermined angle.

16. The apparatus as claimed in claim 15, further comprising a bobbin for fixing the predetermined angle.

17. The apparatus as claimed in claim 12, further comprising a magnetic shield having a tubular shape whose opening extends in the first direction such that the first and second current paths of the bus bar, the magnetic member, and the coil are surrounded by the magnetic shield.
